(19) United States
(12) Patent Application Publication
(10) Pub. No.: US 2025/0286311 A1
(43) Pub. Date: Sep. 11, 2025

(54) METHOD AND DEVICE FOR A THERMAL TREATMENT

(71) Applicant: SCHUNK CARBON TECHNOLOGY GMBH, Bad Goisern (AT)

(72) Inventors: Ludwig Kain, Bad Goisern (AT); Reinhard Schaumburger, Dorf an der Pram (AT); Klaus Hoell, Bad Goisern (AT); Aaron Hutzler, Berlin (DE)

(21) Appl. No.: 18/860,214

(22) PCT Filed: Apr. 21, 2023
(86) PCT No.: PCT/EP2023/060458

§ 371 Date: Oct. 25, 2024

(30) Foreign Application Priority Data
Apr. 28, 2022 (DE) 10 2022 110 381.1

(51) Int. Cl. H01R 13/533; H01R 12/85; H01R 13/03; H01R 13/512; H01R 43/02

(52) U.S. Cl. CPC H01R 13/533; H01R 12/85; H01R 13/03; H01R 13/512; H01R 43/0242

(57) ABSTRACT

The invention relates to a device and a method for thermally treating components, in particular electronic components or the like, the device comprising a batch tray (10) and at least two groups of components placed on the batch tray, the groups of components each comprising at least a first component and a second component connected or to be connected to the first component, the batch tray having at least two tray units (11) each accommodating a group of components. The tray units each have a tray (12) and a connecting member (13) for connecting the trays to each other, the connecting member being formed by at least one connecting element (14), a material of the connecting element and/or the trays being selected in such a manner that the connecting element and/or the tray exhibits thermal expansion in at least one linear direction when thermally treated, said thermal expansion essentially corresponding to a thermal expansion of the first component and/or the second component in the linear direction.

The invention relates to a method and a device for thermally treating components, in particular electronic components or the like, the device comprising a batch tray and at least two groups of components placed on the batch tray, the groups of components each comprising at least a first component and a second component connected or to be connected to the first component, the batch tray having at least two tray units each accommodating a group of components.

Electronic components and circuits are typically produced from a plurality of components, the components or groups of components being joined by thermal treatment for forming an electrically conductive connection. In particular, a bonded and electrically conductive connection is formed between the components by soldering, sintering or the like. The essential aspect is that the soldering or sintering uses a connecting material which is at least partially melted during the thermal treatment or which produces a bonded connection by diffusion. For instance, conductor paths of a first component are connected to contacts of a second component in an electrically conductive manner or electrically isolated areas are bonded in order to obtain a mechanically stable group of components. The thermal treatment can take place in various ways, for example, by local heating of a contact point or by heating entire groups of components. In the course of such a production step, the groups of components or the components are held in the intended contact position relative to each other. This positioning of the components is typically achieved with the aid of batch trays, into which the components are placed and which can accommodate a plurality of groups of components. This makes it possible for these groups of components to be thermally treated simultaneously or one immediately after the other so that large numbers can be produced economically.

The known methods and devices for thermal treatment are disadvantageous in that large temperature differences accompanied by different degrees of thermal expansion can occur on the components to be joined and may cause the components to warp, in particular during cooling. For instance, the cooling components or the cooling joined group of components may warp or become distorted as a result of shrinking. Differences in the thermal expansion of the components have a greater impact on warping than temperature difference within the components. A heating of the batch tray can also cause a relative position of the components to be joined to become imprecise with the result that narrow tolerances are hard to maintain. Depending on the position or the fixation of the components on the batch tray, unintended play or a relative offset of the components can occur as a result of the thermal treatment. Moreover, the entire batch tray may deform to the point that the groups of components are no longer in an intended position relative to a machine pushing the components together at a connecting point by means of an actor, for example. As a result, short circuits or other malfunctions may occur on the group of components.

Hence, the object of the present invention is to propose a device and a method for thermally treating components which enables a more precise production in an economic fashion.

This object is attained by a device having the features of claim 1 and a method having the features of claim 14.

The device according to the invention for thermally treating components, in particular electronic or the like, comprises a batch tray and at least two groups of components placed on the batch tray, the groups of components each comprising at least a first component and a second component connected or to be connected to the first component, the batch tray having at least two tray units each accommodating a group of components, wherein the tray units each have a tray and a connecting member for connecting the trays to each other, the connecting member being formed by at least one connecting element, a material of the connecting element and/or the trays being selected in such a manner that the connecting element and/or the tray exhibits thermal expansion in at least one linear direction when thermally treated, said thermal expansion essentially corresponding to a thermal expansion of the first component and/or the second component in the linear direction.

Accordingly, a plurality of groups of components each comprising at least two components which are connected to each other in an electrically conductive manner or in an electrically non-conductive manner in the course of the thermal treatment can be placed on the batch tray. The groups of components are each placed on a separate tray unit of the batch tray, the tray units being composed of the tray and the connecting member. The batch tray can have 2+n tray units, i.e., a number of tray units that can still be handled by the batch tray in principle. The connecting member serves to attach the trays to each other and has at least one connecting element. If the batch tray is partially or fully heated during a thermal treatment of the respective components, this causes a thermal expansion of the batch tray and at least one component or the group of components. This thermal expansion takes place in relation to a common coordinate system of the batch tray and the group of components in the same at least one linear direction. A material of the connecting element and/or the tray is selected in such a manner that the connecting element and the tray undergo thermal expansion during the thermal treatment, the thermal expansion corresponding to a thermal expansion of at least one of the respective components. In this context, thermal expansion refers to a thermal expansion in at least the linear direction, meaning a change in length. However, the thermal expansion can also relate to a surface or a volume and thus take place in multiple directions. Since the thermal expansion of the connecting element and the trays is approximately equal to the thermal expansion of one of the components of the groups of components, the batch tray can compensate for this thermal expansion of the components in question to such a degree that an unintended relative offset of the components during the thermal treatment and/or a potential warping of the components during cooling after the thermal treatment is prevented. This makes it possible for high-quality groups of components to be produced economically and for narrow tolerances to be maintained during production.

The trays can be connected to the connecting element in a form-fitting manner by means of respective fasteners. In principle, the trays can be separate from each other, i.e., they can be individual components or elements, which are connected by the connecting element. Accordingly, it is possible to space the trays apart in such a manner that a thermal expansion of the trays is not affected by a mutual contact of the trays or propagates across the trays. At the same time, no direct heat transfer between trays can occur. Still, a relative distance between the trays can be very precise owing to the form-fitting connection to the connecting element. This is advantageous in particular if a relative distance of the trays is required in the course of a serial or parallel thermal treatment using a suitable machine. The fastener can comprise a screw, a pin and/or other fastening means, for example. Furthermore, multiple connecting elements can be provided.

The connecting member can be composed of at least two connecting elements, and the connecting elements can be parallel profile rods, which can connect spaced-apart trays. For example, the profile rods can be flat profile rods, along the length of which a number of trays are disposed. The profile rods can preferably be identical so that the connecting member and the batch tray do not warp during thermal treatment. Also, the profile rods can be connected to the trays on an upper side and/or a lower side of the trays so that the components come into contact with the profile rods or are spaced apart from them when positioned on the batch tray.

Each tray unit can be provided with at least one positioning aid and/or a recess for accommodating and positioning the first component and/or the second component. The tray unit can be configured to position or accommodate additional components. Each tray unit or selected tray units only may be provided with a positioning aid. The positioning aid can be a pin, a stop, a rail or the like, for example, which enables a precise and form-fitting positioning of the components on the batch tray. Also, the recess can be used for positioning the components in such a manner. For instance, one of the components or both components can be fully or partially inserted into the recess. In this case, overlapping components can be connected to each other particularly easily. The first component can be a DBC substrate and the second component can be a lead frame, for example.

The connecting element and the trays can be made of different materials. Using different materials for the trays and the at least one connecting element makes it possible for a temperature conductivity and a thermal expansion of the batch tray to be influenced differently. The materials can be selected in such a manner that the batch tray has at least a thermal expansion adapted to the thermal expansion of the group of components or the first and/or the second component. Alternatively, the connecting element and the trays can be made of the same materials.

However, the first component and the second component can be made of different materials. In principle, it is also possible for the components themselves to be made of different materials. This can result in different thermal conductivities and thermal expansions of the respective components or the groups of components. Alternatively, the first component and the second component can be made of the same materials.

The material of the connecting element or the trays can be identical to a material of the first component. Accordingly, the material of the connecting element or the trays can be selected according to a material of the first component. The essential aspect is that the material of the connecting element or the trays and the material of the first component have similar physical properties with regard to thermal expansion, such as a maximum difference of the thermal expansion coefficient of ±5×10⁻⁶/K. This makes it possible for a thermal expansion of the connecting element or the trays to be adapted particularly easily to a thermal expansion of the first component depending on the geometrical shape of the connecting element or the trays. In this context, identical materials also mean essentially similar materials, such as copper and alloys of copper.

The material of the connecting element or the trays can be a material having an anisotropic thermal expansion coefficient. The thermal expansion coefficient of the material consequently differs depending on a positon of a structure of the material, such as a crystal lattice or a reinforcement. In this manner, the connecting element or the tray can be configured with varying thermal expansions. For instance, the connecting element or the trays can be arranged in such a manner that a particularly low thermal expansion takes place in a certain liner direction so that only a small relative offset or no relative offset between the components of a group of components occurs when the batch tray is heated.

The material can be a composite material, graphite, preferably aluminum graphite, or ceramic, preferably aluminum silicon carbide. The connecting element and/or the trays can in particular be made of one of these materials. In particular graphite or a modification of graphite can have an anisotropic thermal expansion coefficient. Furthermore, aluminum graphite has a particularly high heat conductivity. If the tray is made of aluminum graphite, the group of components can be heated particularly quickly via the tray using a heating plate, for example. In this manner, cycle times can be reduced significantly. Also, materials having a particularly low heat conductivity can be used, for example, if only partial heating of the group of components is intended.

Furthermore, the material of the connecting element or the trays can be a metal, preferably copper or aluminum, or a ceramic. Copper and aluminum have a relatively high heat conductivity, which means that these metals can be advantageously used for forming the connecting element or the trays. A high heat conductivity and thus a high thermal conductivity are advantageous if a quick introduction and discharge of thermal energy at the group of components is intended. At the same time, the thermal conductivity can also be used to establish as small or as large a temperature gradient as possible within the batch tray or the connecting element or the trays and thus accelerate or suppress thermal expansion during heating of the batch tray and the groups of components.

A thermal expansion coefficient α_{M} of a material of the connecting element and/or the trays and a thermal expansion coefficient αₘ of a material of the first component and/or the second component can deviate by ≤20×10⁻⁶/K, preferably ≤10×10⁻⁶/K, particularly preferably ≤5×10⁻⁶/K, or be equal. The values mentioned relate to a temperature of 20° C. Approximately equal or equal thermal expansion coefficients effect a more homogenous thermal expansion of the connecting element and/or the trays compared to the first and/or the second component or the group of components. Furthermore, the materials of the connecting element and the tray can have very different thermal expansion coefficients, which for their part are adapted to the respective materials of the first component and the second component.

A thermal conduction coefficient λ of a material of the connecting element and/or the trays can be ≥100 W/(m×K), preferably ≥200 W/(m×K), particularly preferably ≥300 W/(m×K). Such a high heat conductivity of the material promotes quick heating or cooling of the material, i.e., the connecting element and/or the trays. As a result, a process for thermally treating the group of components can be accelerated significantly since joining and post-treatment of the respective components can happen fast. In principle, the thermal conduction coefficient of the material of the connecting element and the tray can differ greatly. In this manner, good heat conduction can be provided where quick heating of the group of components is favorable.

A thermal conductivity α_{V}, α_{T} of the connecting element and/or the trays and a thermal conductivity α_{1B}, α_{2B} of the first component and/or the second component can deviate from each other by ≤5 mm²/s, preferably ≤3 mm²/s, particularly preferably ≤1 mm²/s, or be equal. The values mentioned relate to a temperature of 20° C. Thermal conductivity refers to heat conductivity divided by the product of density and specific heat capacity. The connecting element and/or the tray can have such a geometrical shape and such a mass that the connection of the trays to the respective material of the connecting element results in a high or low thermal conductivity. This thermal conductivity can in turn be adapted to a thermal conductivity of the respective components or the group of components. If the respective heat flows can then spread simultaneously and evenly in the connecting element and/or the trays and the respective components, a correspondingly adapted parallel thermal expansion of the connecting element and/or the trays with the respective components can be achieved. Furthermore, a high thermal conductivity allows reducing a temperature gradient within the batch tray. This is advantageous since it means that the batch tray and the components to be joined can be prevented from warping relative to a machine.

In the method according to the invention for thermally treating components, in particular electronic components or the like, at least two groups of components are placed on at least two tray units of a batch tray, the tray units each accommodating a group of components, the groups of components each being composed of at least a first component and a second component to be connected to the first component, a connecting material being at least partially melted or diffused and the first components being bonded to the second components in at least one connecting area of each of the first components and the second components by a thermal treatment or thermal energy of a heating device, wherein a tray of each tray unit and/or at least one connecting element of a connecting member for connecting the trays to each other undergoes thermal expansion in at least one linear direction during the thermal treatment, said thermal expansion essentially corresponding to a thermal expansion of the first component and/or the second component in the linear direction. Regarding the advantages of the method according to the invention, reference is made to the description of advantages of the device according to the invention.

The heating device can be used to melt a solder as a connecting material or to sinter a metal paste, preferably silver paste or copper paste, as a connecting material; the heating device can be a heating plate and/or a furnace. The method can be used to solder electronic components using soldering plants or for silver-sintering or copper-sintering electronic components using a suitable machine. The soldering and the sintering can take place using a heating plate of the machine and/or using a furnace. The batch tray can be brought in direct contact with the heating plate, the group of components thus being heated. Alternatively, the batch tray can be heated together with the group of components in a furnace.

During the thermal treatment of the first components and the second components, the connecting element and/or the trays and the first components and/or the second components can be heated or cooled at different rates; a material of the connecting element and/or the trays can be selected in such a manner that the first components and/or the second components thermally expand in the same manner as the connecting element and/or the trays. Consequently, the thermal expansion of the connecting element and/or of the trays can compensate for the thermal expansion of the first components and/or the second components or the respective groups of components in such a manner that a simultaneous and homogeneous thermal expansion takes place. In this manner, warping of the components can be suppressed and a connecting contact of the components to the respective tray units can be improved with the result that a particularly good heat transfer between the tray unit and the group of components can be ensured.

During the thermal treatment, the first components, the second components and the trays can thermally expand; the first components, the second components and the trays can be positioned coplanar relative to each other. Consequently, the components and the tray do not change position relative to each other during the thermal treatment.

During the thermal treatment, a temperature gradient of ≤15 K, preferably ≤10 K, particularly preferably ≤5 K, can form within the tray. Advantageously, a small temperature gradient can also be achieved by high thermal conductivity and ensures a homogeneous heat distribution within the tray. Warping due to an inhomogeneous heat distribution can be avoided in this manner.

Other advantageous embodiments of the method are apparent from the description of features of the dependent claims referring to device claim 1.

Hereinafter, a preferred embodiment of the invention will be discussed in more detail with reference to the accompanying drawings.

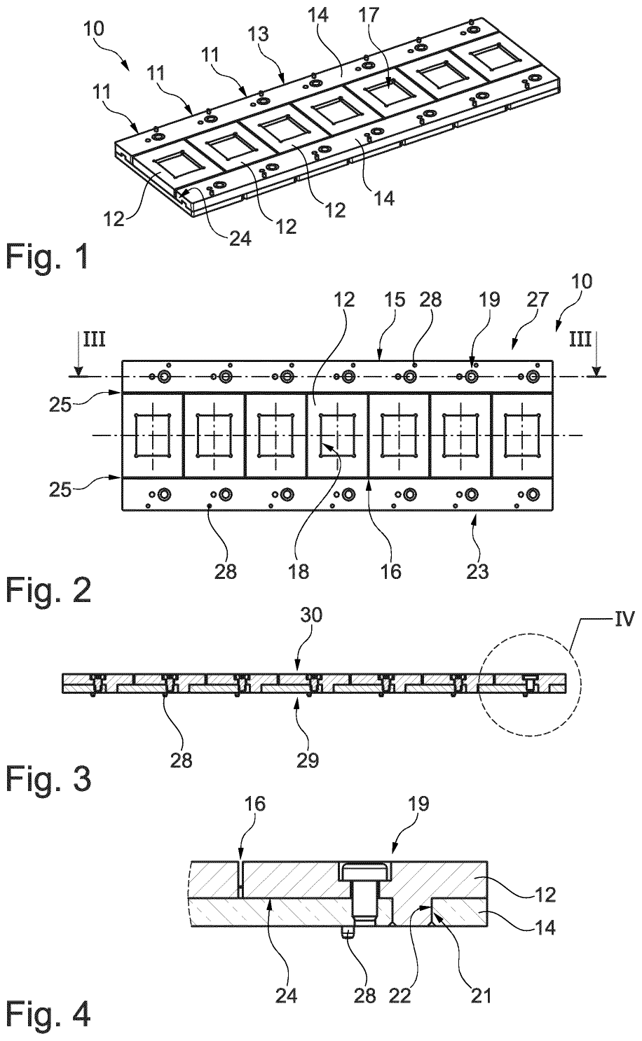

FIG. 1 is a perspective view of a batch tray;

FIG. 2 is a top view of the batch tray;

FIG. 3 is a section view of the batch tray of FIG. 2 along Line III-III;

FIG. 4 is a detail view IV of the batch tray of FIG. 3.

A combined view of FIGS. 1 to 4 shows a batch tray 10, which serves to accommodate a plurality of groups of components (not shown), the groups of components being supplied to a thermal treatment together with the batch tray. The groups of components each comprise at least a first component and a second component, which is to be connected, i.e., bonded, to the first component in an electrically conductive or electrically non-conductive manner, an electrically conductive bonded connection between the two components being formed by at least partially melting or diffusing connecting material, such as solder or a metal paste, by the thermal treatment. Alternatively, merely a thermal treatment of already formed or joined groups of components may be intended.

Batch tray 10 forms a row of tray units 11, each tray unit 11 being able to accommodate a group of components. Tray units 11 are each composed of a tray 12 and a connecting member 13 for connecting trays 12. In particular, connecting member 13 is composed of two connecting elements 14 in the case at hand. Each connecting element 14 is a profile rod 15 and consists of copper. Alternatively, profile rod 15 can consist of aluminum. Connecting elements 14 connect trays 12, which are spaced apart a little by a narrow gap 16 in the row arrangement shown. Trays 12 are provided with a recess 17 for accommodating a first component (not shown) of the group of components. The first component can be a DCB substrate. Recess 17 is configured in such a manner that the first component can be inserted into it and be positioned or fixed in an intended position by a contour 18 of recess 17. Trays 12 consist of aluminum graphite.

Batch tray 10 further comprises a fastener 19, which serves to connect connecting elements 14 to trays 12 in a form fitting manner. Fastener 19 comprises screws 20 and pins 21, which are formed by trays 12 or molded thereto, pins 21 being inserted into corresponding passage openings 22 in connecting elements 14. The engagement of pins 21 with passage openings 22 establishes a form-fitting connection between trays 12 and connecting elements 14. At the same time, respective screws 20 fix trays 12 to connecting elements 14 in a tight form-fitting and force-fitting manner. Moreover, a shoulder 24, whose depth approximately corresponds to a height of connecting elements 14, is formed on respective longitudinal sides 23 of trays 12. Connecting elements 14 are inserted into said shoulder 24 in an essentially flush manner, shoulder 24 being configured in such a manner that a small gap 25, which extends along the longitudinal direction or a longitudinal axis 26 of batch tray 10, is also formed between respective connecting elements 14 and trays 12.

The aluminum graphite of respective trays 14 has an anisotropic thermal expansion coefficient. Also, a positioning aid 27 for components is provided on each connecting element 14, positioning aid 27 being formed by a pin 28 in the case at hand. In particular, this allows a copper plate or a lead frame (not shown) to be placed in a precise position on an upper side 29 of batch tray 20 as a second component, which can be produced using a die cutting tool. Pins 28 can engage in passage openings of the copper plate, for example, and position it correctly in this manner.

A thermal treatment can now take place by bringing a heating plate (not shown) into contact with a lower side 30 of batch tray 10, the heating plate heating batch tray 10. This heating continues until a temperature which at least partially melts the connecting material is reached, whereupon batch tray 10 is cooled again and the connecting material hardens with the result that a bonded and electrically conductive connection is formed between the first component and the second component.

As the batch tray is being heated using the heating plate, the high thermal conductivity of the aluminum graphite of trays 12 leads to a quick heating of the components in this area. Thermal expansion perpendicular to longitudinal axis 26 is low since the expansion coefficient of the aluminum graphite in this direction is also low. A thermal expansion of trays 12 along longitudinal axis 26, on the other hand, is of little significance since trays 12 are spaced apart by gap 16. Since connecting elements 14 have essentially the same expansion coefficient as the die-cut copper plate, a thermal expansion of the batch tray together with the copper plate along longitudinal axis 26 is essentially the same. Hence, neither an unintended offset of the first component and the second component during the thermal treatment nor a potential deformation during cooling occur. The same applies to a thermal expansion of respective trays 12 and the respective first components placed in recesses 17. Here, too, a thermal expansion of trays 12 is dimensioned in such a manner that the first components are in contact with contour 18 and are not shifted. In this manner, particularly narrow tolerances can be maintained when producing electronic components and a production process can be accelerated advantageously.

1. A device for thermally treating components, in particular electronic components or the like, the device comprising a batch tray (10) and at least two groups of components placed on the batch tray, the groups of components each comprising at least a first component and a second component connected or to be connected to the first component, the batch tray having at least two tray units (11) each accommodating a group of components,
characterized in that
the tray units each have a tray (12) and a connecting member (13) for connecting the trays to each other, the connecting member being formed by at least one connecting element (14), a material of the connecting element and/or the trays being selected in such a manner that the connecting element and/or the tray exhibits thermal expansion in at least one linear direction when thermally treated, said thermal expansion essentially corresponding to a thermal expansion of the first component and/or the second component in the linear direction.

2. The device according to claim 1,
characterized in that
the trays (12) are connected to the connecting element (14) in a form-fitting manner by means of respective fasteners (19).

3. The device according to claim 1,
characterized in that
the connecting member (13) is composed of at least two connecting elements (14), the connecting elements being parallel profile rods (15) connecting spaced part trays (12).

4. The device according to claim 1,
characterized in that
each tray unit (11) is provided with at least one positioning aid (27) and/or a recess (17) for accommodating and positioning the first component and/or the second component.

5. The device according to claim 1,
characterized in that
the connecting element (14) and the trays (12) are made of different materials.

6. The device according to claim 1,
characterized in that
the first component and the second component are made of different materials.

7. The device according to claim 1,
characterized in that
the material of the connecting element (14) or the trays (12) is identical to a material of the first component.

8. The device according to claim 1,
characterized in that
the material of the connecting element (14) or the trays (12) is a material having an anisotropic thermal expansion coefficient.

9. The device according to claim 1,
characterized in that
the material is a composite material, graphite, preferably aluminum graphite, or ceramic, preferably aluminum silicon carbide.

10. The device according to claim 1,
characterized in that
the material of the connecting element (14) or the trays (12) is a metal, preferably copper or aluminum, or a ceramic.

11. The device according to claim 1,
characterized in that
a thermal expansion coefficient (α_{M}) of a material of the connecting element (14) and/or the trays (12) and a thermal expansion coefficient (αₘ) of a material of the first component and/or the second component deviate from each other by ≤20×10⁻⁶/K, preferably ≤10×10⁻⁶/K, particularly preferably ≤5×10⁻⁶/K, or are equal.

12. The device according to claim 1,
characterized in that
a thermal conduction coefficient (λ) of a material of the connecting element (14) and/or the trays (12) is ≥100 W/(m×K), preferably ≥200 W/(m×K), particularly preferably ≥300 W/(m×K).

13. The device according to claim 1,
characterized in that
a thermal conductivity (α_{V}, α_{T}) of the connecting element (12) and/or the trays (14) and a thermal conductivity (α_{1B}, α_{2B}) of the first component and/or the second component deviate from each other by ≤5 mm²/s, preferably ≤3 mm²/s, particularly preferably ≤1 mm²/s, or are equal.

14. A method for thermally treating components, in particular electronic components or the like, in which at least two groups of components are placed on at least two tray units (11) of a batch tray (10), the tray units each accommodating a group of components, the groups of components each being composed of at least a first component and a second component to be connected to the first component, a connecting material being at least partially melted or diffused and the first components being bonded to the second components in at least one connecting area of each of the first components and the second components by a thermal treatment of a heating device,
characterized in that
a tray (12) of each tray unit and/or at least one connecting element (14) of a connecting member (13) for connecting the trays to each other undergoes thermal expansion in at least one linear direction during the thermal treatment, said thermal expansion essentially corresponding to a thermal expansion of the first component and/or the second component in the linear direction.

15. The method according to claim 14,
characterized in that
the heating device is used to melt a solder as a connecting material or to sinter a metal paste, preferably silver paste or copper paste, as a connecting material, the heating device being a heating plate and/or a furnace.

16. The method according to claim 14,
characterized in that
during the thermal treatment of the first components and the second components, the connecting element (14) and/or the trays (12) and the first components and/or the second components are heated or cooled at different rates, a material of the connecting element and/or the trays being selected in such a manner that the first components and/or the second components thermally expand in the same manner as the connecting element and/or the trays.

17. The method according to any one of claim 14,
characterized in that
the first components, the second components and the trays (12) thermally expand during the thermal treatment, the first components, the second components and the trays being positioned coplanar relative to each other.

18. The method according to any one of claim 14,
characterized in that
a temperature gradient of ≤15 K, preferably ≤10 K, particularly preferably ≤5 K, is established within the tray (12) during the thermal treatment.
